(19) United States
(12) Patent Application Publication
(10) Pub. No.: US 2010/0019773 A1
(43) Pub. Date: Jan. 28, 2010

(54) BATTERY MONITORING DEVICE

(76) Inventor: Hong K. SON, Edison, NJ (US)

Correspondence Address: LRK Patent Firm, 1952 Gallows Rd Suite 200, Vienna, VA, 22182, US

(21) Appl. No.: 12/180,647

(22) Filed: Jul. 28, 2008

(51) Int. Cl. G01R 31/36

(52) U.S. Cl. 324/431

(57) ABSTRACT

A battery monitoring device includes a probe for insertion into a valve of a lead acid battery. The probe includes an electrolyte monitoring probe connected to an electrolyte level sensor, and a temperature probe connected to a temperature sensor. The battery monitoring device also includes a display for communicating the temperature and electrolyte level of the lead acid battery, and an LED for indicating that the electrolyte level is low. At appropriate intervals, the battery monitoring device can deliver pulses of electricity to the lead acid battery and counteract sulfation, in order to enhance battery performance and extend the useful lifetime of the battery.

### INTRODUCTION

The present discussion relates to a battery monitor for enhancing the operation of lead acid batteries, which can be used with existing batteries, and which can improve charge capacity and extend the useful life of various types of batteries.

### BACKGROUND

Lead acid batteries are a class of rechargeable electrochemical cells that are widely used in industrial, automotive, marine and household applications. Among the advantages of lead acid batteries are their low cost and their ability to deliver high surge currents (as required for automobile starter motors, for example). In addition, the chemistry of lead acid batteries is relatively uncomplicated, to the extent that the majority of automobile batteries found in cars and trucks worldwide, as well as the batteries that power industrial equipment such as forklifts, are based on plates of common metallic lead immersed in an electrolyte of water and sulfuric acid (see, for example, FIG. 1).

However, certain factors and effects of lead acid batteries can reduce their useful lifetime, and therefore necessitate costly replacement or reconditioning. One such effect is sulfation, which can eventually prevent such batteries from accepting or retaining an electric charge. Sulfation is often observed when a lead acid battery has been left in a discharged state for a substantial period of time, which promotes crystalline lead sulfate—an electrical insulator—to be deposited as a layer coating the electrodes and other internal components of the battery.

Lead acid batteries generate electricity through a double sulfate chemical reaction, in which lead and lead dioxide, which are the active materials on the battery's cell plates, react with sulfuric acid in the electrolyte. As a result, lead sulfate is formed, which occurs initially in a finely divided, amorphous form that is readily convertible back to useful metallic lead, lead oxide and sulfuric acid when the battery is recharged.

Over time, however, lead sulfate can convert from the amorphous state to a more stable, largely inert crystalline form that accumulates on the electrodes and cell plates of the battery. Crystalline lead sulfate does not conduct electricity and is not convertible back into lead and lead oxide under normal charging conditions. Therefore, as lead acid batteries cycle through numerous discharge and charge sequences, the beneficial amorphous form of lead sulfate that is generated during normal discharge is gradually converted to the detrimental crystalline form. This process is known as sulfation.

The effects of sulfation clog battery grids, impede recharging and can even expand and crack battery cell plates as the crystalline lead sulfate accumulates, destroying the battery. Crystalline lead sulfate is resistant to normal charging current, and does not re-dissolve completely. Thus, not all of the lead consumed during discharge is returned to the battery plates during recharge, and the amount of usable active material necessary for generating electricity declines over time.

Sulfation also adversely affects the charging cycle, resulting in longer charging times, less efficient and incomplete charging, excessive heat generation (higher battery temperatures). Increased battery temperatures can cause longer cool-down times and accelerate corrosion. Sulfation is particularly harmful when batteries are stored or not operated for period of time, while in a state of depleted charge, in part because recrystallization occurs in the absence of the usual cycles of breakdown and regeneration of amorphous lead sulfate that occur during normal operation and recharging activities.

As one approach for counteracting the harmful effects of sulfation, U.S. Pat. No. 6,730,428 to KONDO et al., which issued May 4, 2004 (and which is hereby incorporated by reference in its entirety), discusses a pulsating direct current (DC) voltage that is superimposed onto a charging voltage using a DC pulse generating device connected in parallel with a charging device. However, KONDO et al. relates only to a method for recycling lead acid batteries, and does not address extending the useful life or enhancing the performance of existing batteries. Moreover, there are additional factors that can adversely impact useful battery life and performance.

In addition to sulfation, reduced lead acid battery life can also occur because of sub-optimal or insufficient levels of electrolyte being present in the battery, inter alia. In particular, many varieties of lead acid batteries experience gradual loss of electrolyte fluid as a normal part of the battery's use cycle, which can be caused by evaporation due to heat generated as a by-product during discharge or recharging.

For this reason, manufacturers of such batteries recommend that operators of battery-powered equipment (such as forklift vehicles) inspect the water and/or electrolyte levels of their batteries at regular intervals, and add supplemental water or electrolyte as necessary. However, the process of checking water or electrolyte levels typically requires the operator to perform an inconvenient series of steps in order to access the batteries (for example, having to first open a battery compartment of a vehicle, then unscrew a valve cap on each cell in a battery pack in order to check fluid levels, and finally to replace the valve caps and close the battery compartment). Moreover, the rate of fluid loss can vary depending on how often or how long the battery-powered equipment is operated, as well as ambient or internal battery temperature, inter alia, which can reduce the usefulness of a battery inspection schedule based on regular intervals. As a result, battery electrolyte levels frequently go unchecked despite possible adverse effects on the batteries, leading to substantially increased operation or replacement costs for batteries that wear out early due to having been operated with insufficient fluid levels.

As one example approach for avoiding early battery wear, U.S. Pat. No. 5,936,382 to JONES et al., which issued Aug. 10, 1999 (and which is hereby incorporated by reference in its entirety), relates to an electrolyte monitor used in combination with a battery having multiple cells, in which the monitor includes a circuit having an indicator which operates when the electrolyte level is at or above the minimum acceptable electrolyte level. Other approaches for dealing with battery monitoring are set forth in U.S. Pat. No. 4,388,584 to DAHL et al., which issued on Jun. 14, 1983, U.S. Pat. No. 5,656,919 to PROCTOR et al., which issued Aug. 12, 1997, and US Pre-grant Publication 2005/0213867 A1 to RAJENDRAN et al., published Sep. 29, 2005, each of which are hereby incorporated by reference in their entireties.

However, in order to retrofit a conventional electrolyte monitor onto existing batteries, it is necessary to tap or drilling into the casing of the existing batteries. This can be dangerous because of the risk of ejecting harmful battery electrolyte (which contains sulfuric acid in aqueous or gelled solution, in the case of lead acid batteries) onto the retrofitter's own exposed eyes or skin, or onto people or equipment in the vicinity of the battery. The casings of lead acid batteries are typically made of thick, tough plastic, which renders drilling difficult and thus heightens the risk of accidents.

Furthermore, even careful drilling of holes to enable the insertion of conventional electrolyte monitors into batteries nonetheless can result in harmful accumulation of resinous build-up, oily films and debris around the site of the drilled hole, caused by the emission of steam and other gases during battery operation.

Also, conventional electrolyte monitors do not include the ability to monitor battery temperature, nor to counteract the harmful effects of sulfation, which are an important factors that can affect battery life and performance.

### SUMMARY

Accordingly, in view of the above and other impediments to the continuing usefulness of lead acid batteries, the present discussion relates to a battery monitor that can be applied to existing batteries. The battery monitor may include a probe that can be inserted into a valve of a battery and a warning indicator for alerting an operator. The battery monitor may also include a surge pulse generator for delivering a surge pulse to the battery.

### BRIEF DESCRIPTION OF THE DRAWINGS

FIG. 1 illustrates a forklift as an example of electric-powered equipment employing lead acid batteries.

FIG. 2A is a perspective cutaway view of a lead acid battery including a valve.

FIG. 2B is a profile cutaway view of a lead acid battery having lead plates immersed in electrolyte solution.

FIG. 3A is a perspective view of an example battery monitoring device.

FIG. 3B is a plan view of the example battery monitoring device.

FIG. 4A is a perspective view of two batteries connected to the example battery monitoring device.

FIG. 4B is a plan view of two batteries connected to the example battery monitoring device.

FIG. 5A is a partial cut-away profile view of a probe of the example battery monitoring device.

FIG. 5B is a plan view of the probe of FIG. 5A.

FIG. 6A is a perspective view of a battery valve cap.

FIG. 6B is a plan view of a battery valve opening.

FIGS. 7A and 7B are partial cut-away perspective views of example battery probes.

FIG. 8 is a cut-away profile view of a battery with the probe of FIG. 7B disposed in the valve well of the battery.

FIG. 9 is a plan view of a battery array connected to an example battery monitoring device.

FIG. 10 is a system-level block diagram illustrating an example functional unit organization of a battery monitoring device.

FIG. 11 is a circuit-level block diagram illustrating an example circuit organization of a battery monitoring device.

### DETAILED DESCRIPTION

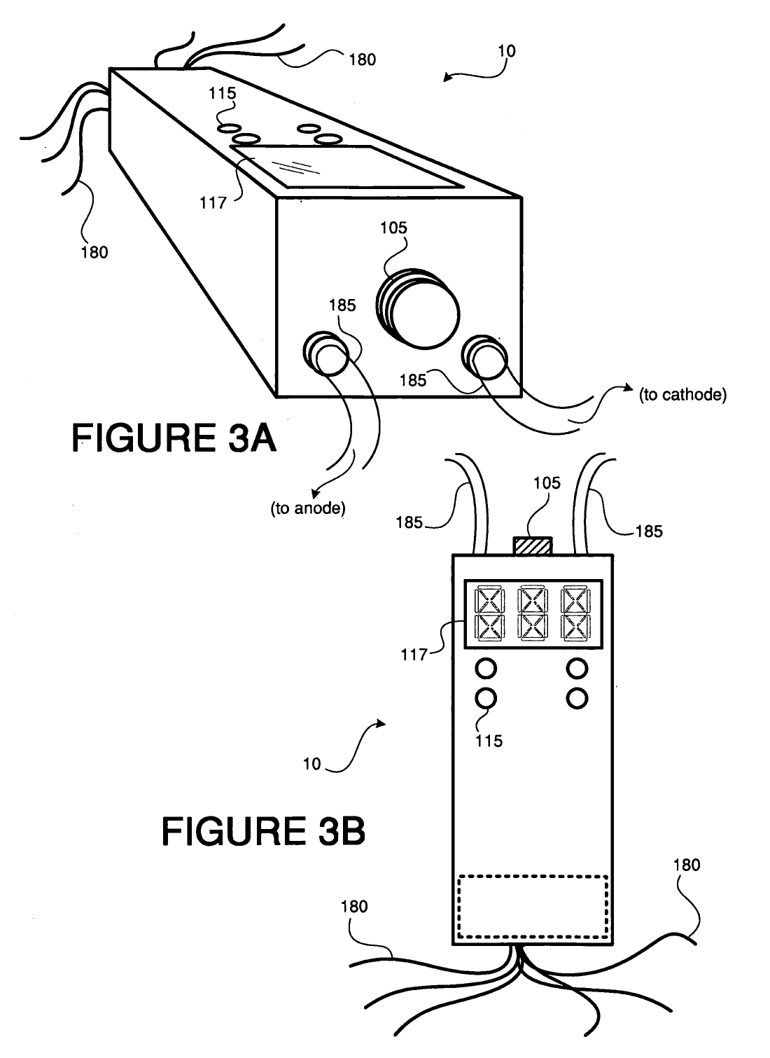

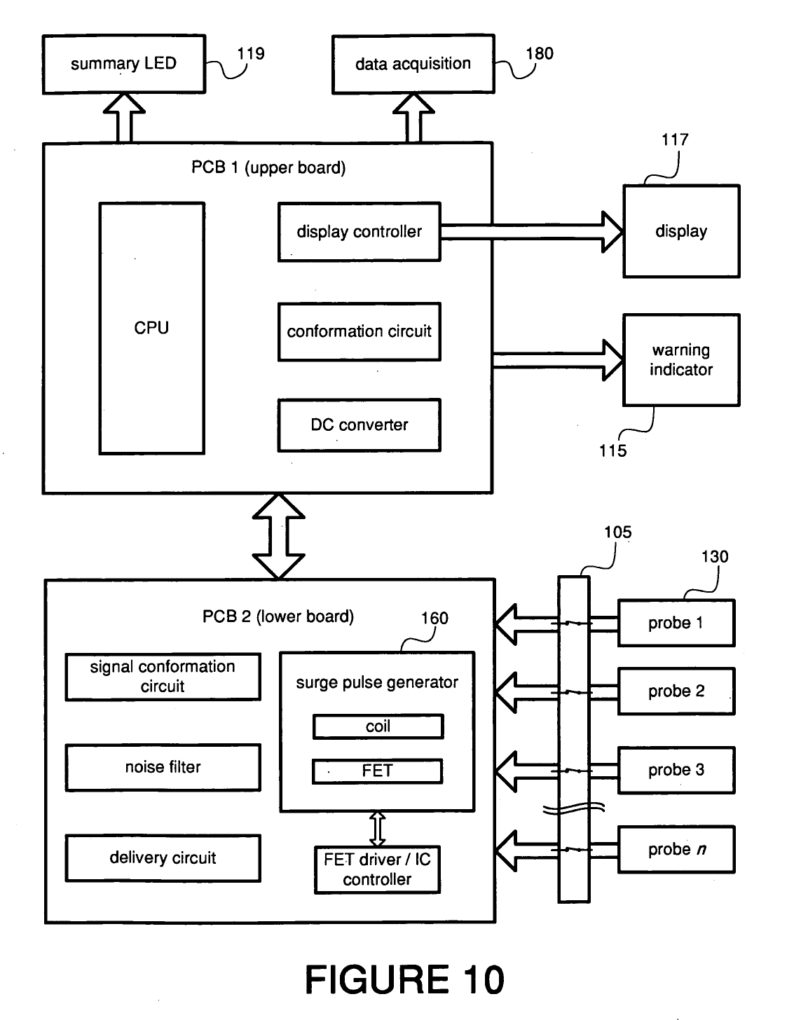

In a first example, a battery monitoring device 10 may include a body made of plastic, or other suitable corrosion-resistant material, which can be disposed on one or more batteries 20 to which the device is connected in order to monitor the battery. The body is preferably made of a water-resistant material, in order to avoid damage or possible short-circuits when water or electrolyte fluid is supplied to the battery. A fuse 105 may also be provided in the battery monitoring device 10, in order to prevent short-circuiting (see, for example, FIGS. 3A, 3B and 10).

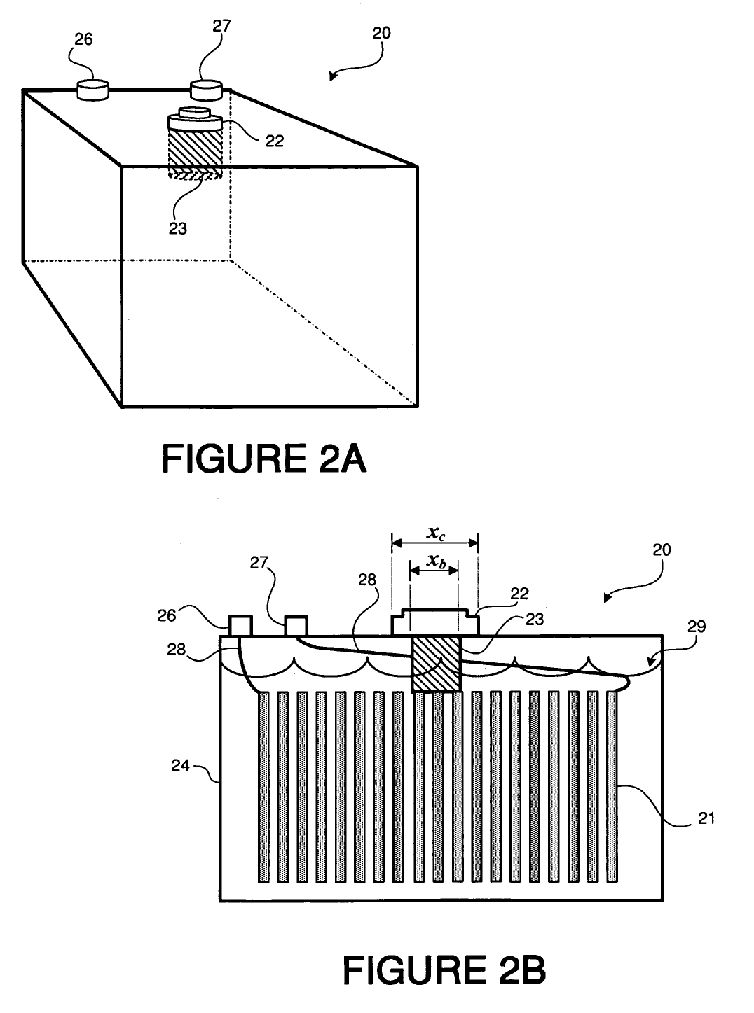

FIGS. 2A and 2B illustrate a lead acid battery 20 that can be monitored by the present battery monitoring device 10. The battery 20 may include a casing 24, an anode 26 and a cathode 27 each extending from the casing 24, and a valve 23 extending into the battery and having a valve cap 22 for releasing gases (such as hydrogen and oxygen, or water vapor) produced as byproducts of the battery discharge or recharging cycles.

Because some types of lead acid batteries, such as “flooded” deep-cycle batteries as commonly used in forklifts and building cleaning equipment, may release hydrogen and oxygen formed from electrolysis that can occur during rapid recharging, a majority of lead acid batteries of this type include a valve for releasing these gases before they accumulate to potentially explosive levels in the battery.

Also, as noted above, even normal battery operation can cause sulfation to occur in the battery 20. During sulfation, the electrically insulating crystalline form of lead sulfate is deposited on electrodes and/or lead plates within the battery casing. These accumulations of lead sulfate tend to raise the internal resistance of the battery.

In order to counteract sulfation and also reduce the risk of low electrolyte levels, one example embodiment provides a battery monitoring device 10 having a surge pulse generator 160 and a probe 130 that can monitor electrolyte levels 29 in the battery 20, where the probe 130 is communicatively coupled to the battery monitoring device 10 by a probe line 180 (such as an insulated wire). In accordance with one example arrangement, the battery monitoring device 10 also includes a temperature sensor 156 capable of detecting the temperature of the battery 20. By applying one or more surge pulses to a battery during recharging, lead sulfate deposits can be broken up and the usefulness of the battery 20 can be enhanced.

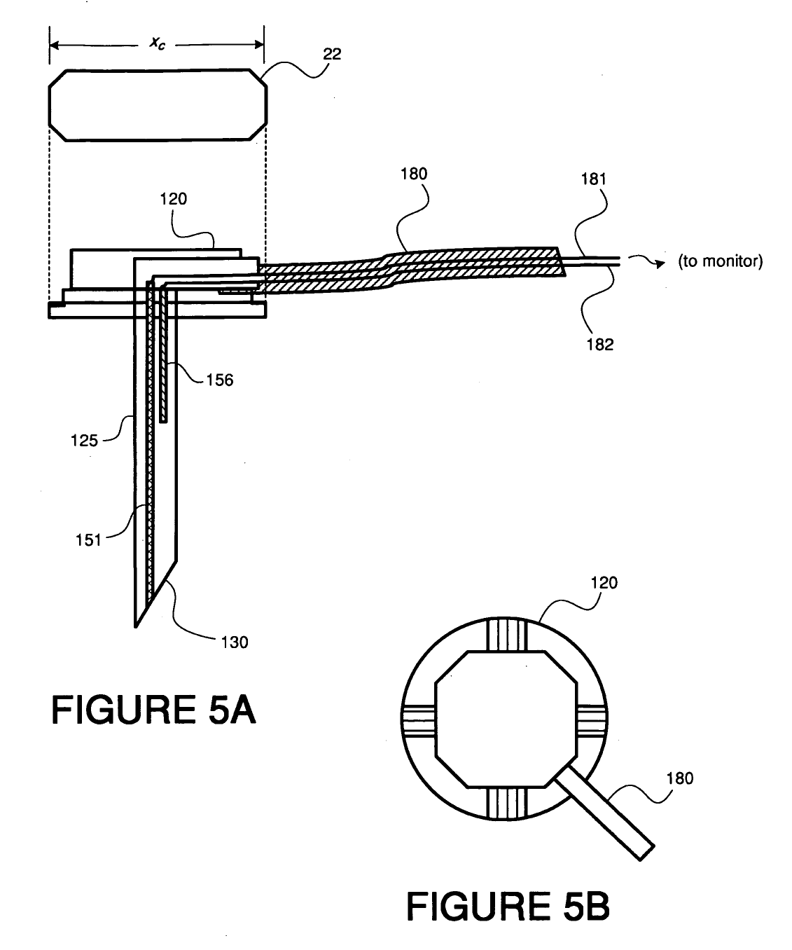

As illustrated in FIGS. 2B, 5, 6A, 6B, 7A and 7B, the probe 130 of the battery monitoring device 10 may have a form factor that permits the probe 130 to be inserted into the existing valve 23 of a battery 20. Reduced costs can by achieved, because installation of a battery monitoring device 10 that does not require drilling a new hole permits the expense and risk of battery casing modifications to be omitted. In one example embodiment, as illustrated in FIG. 7A, the probe 130 may be formed by modifying a pre-existing valve cap 22 (such as may be normally supplied as a standard or stock part with an existing battery, for example), upon inserting sensors 151 through the top or other surface of the valve cap 22. In an alternative embodiment, as illustrated in FIG. 7B, the probe 130 may instead be constructed as an integrated unit by a molding process or die casting (when formed as an integrated unit, the probe line 180 may extend laterally outward from the probe 130 in order to facilitate probe line placement).

In order to reliably retain the probe 130 within the valve 23, the upper portion of the probe 130 may include threading, a semi-flexible locking lip similar to those found on the caps of non-childsafe medicine bottles, or another fastening mechanism. In at least one embodiment, the fastening mechanism of the probe 130 is selected to be the same as or similar to that of the valve cap 22 when the valve 12 was previously covered by a valve cap 22 provided with the battery 20 from the manufacturer.

The probe 130 may include a flexible tube-shaped sheath 125 loosely surrounding the electrolyte sensor 151, in one example. Alternatively, in order to prevent false electrolyte level readings that may be caused by condensation or capillary rising of electrolyte fluid 29 into interstitial space between the interior of the sheath and the electrolyte sensor, the probe 130 may form a water-tight (and/or vapor-proof) seal at the top of the valve 23 in order to prevent foreign material from being introduced into the battery and/or to prevent escape of electrolyte from the battery 20. In one example, the sheath 125 may include a rigid or semi-rigid plastic (such as acrylonitrile butadiene styrene, α-methyl-styrene copolymer-based plastics, etc.), or or glass (e.g., silica- or alumina-based) material formed in one piece with the electrolyte sensor.

For another example, where the valve 23 has an opening having a diameter x_{b}, then the probe 130 may include a probe retainer 120 having a diameter x_{c} where x_{c} is greater than x_{b}. As a result, the probe retainer 120 can effectively seal or isolate the valve 23 from the surrounding environment, while securing the electrolyte sensor 151 in the valve 23.

In various markets around the world, there is often a standard valve shape and/or size among batteries of similar type. Also, the fastening mechanism by which valve caps 22 are secured to the battery 20 may be of a standard type, using a technology such as screw threading or a notched lip 221 disposed at the opening of the valve 23. In accordance with one example embodiment, the probe retainer 120 of the battery monitoring device 10 has a general shape and size compatible with or identical to the shape and/or size of the valve cap 22. In addition, the probe fastener 120 may include a fastening mechanism that is functionally and/or structurally compatible with the valve cap 22, so that the probe 130 can be attached to the valve 23 of the battery 20 in a manner substantially the same as the valve cap 22 it replaces.

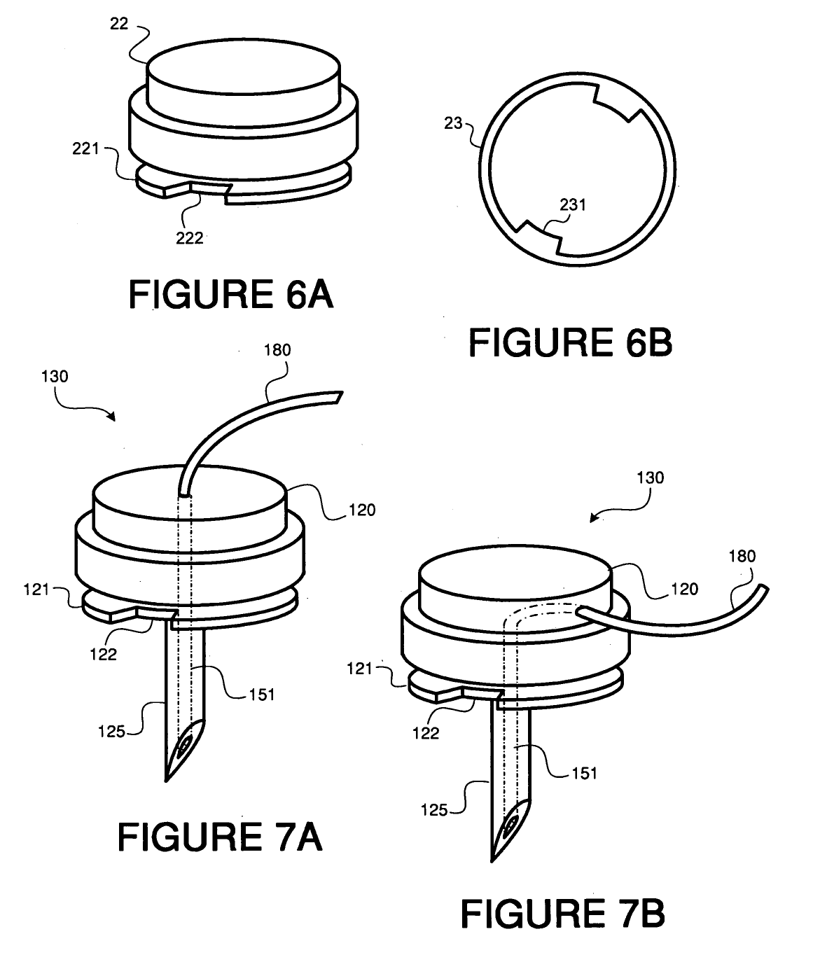

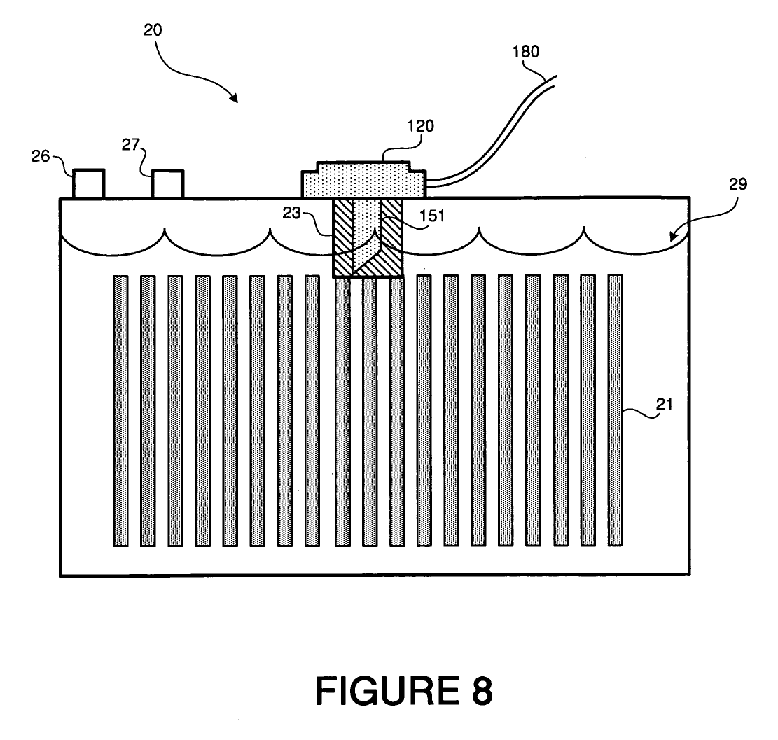

As illustrated in FIGS. 6A and 6B, the opening of one example valve 231 has a protrusion 231 that extends inward. The valve cap 22 includes a lip 221 having a notch 222 of the same shape and dimensions corresponding to the battery valve's protrusion 231. Likewise, the probe retainer 120 of the example probe 130 illustrated in FIGS. 7A and 7B has a retaining lip 121 and retaining lip notch 122 substantially the same as the valve cap 22, such that the probe 130 is attachable to the opening of the valve 23 by inserting the lip 121 downward with the notch 122 in alignment with the protrusion 231, and then rotating the probe retainer 120 so that the notch 122 is no longer aligned with the protrusion 231 and the lip 121 abuts against the protrusion 231, thereby securing the probe 130 in the opening of the valve 23. To detach the probe 130 from the valve 23, the probe retainer 120 may be twisted back until the notch 122 is again aligned with the protrusion 231, and then lifting the probe 130 out from the battery 20. Alternatively, the probe retainer 120 may include screw threading, a “snap” lid, adhesive material such as glue or epoxy, or any other structure for retaining the probe 130 in the valve 23 of the battery 20.

In one example arrangement, the probe 130 of the battery monitoring device 10 includes both the electrolyte level detecting sensor 151 and the temperature sensor 156 in one integrated valve probe 130 that can be inserted into the valve 23 of a battery. The temperature sensor 156 may be very thin, to facilitate installation of the probe 130. As one non-limiting example, when a battery 20 has an existing valve 23 with a diameter of 30 millimeters, then the width of the probe tip may be selected to be less than thirty millimeters, in order to permit insertion into the existing valve of such a battery. The temperature sensor 156 may include a thermocouple (e.g., a bimetallic strip) or a variable-resistance temperature sensor, for example, or may include a temperature sensor such as any of those discussed in RAJENDRAN et al., or any other kind of temperature sensing device suitable for being inserted into the valve 23 of a battery 20.

The battery monitoring device 10 may deliver a surge pulse or a series of surge pulses to the battery 20 when the battery is being recharged. The surge pulse may be generated in a manner similar to that discussed in KONDO et al., for example, or in any other way suitable for the battery monitoring device 10 to deliver surge pulses for disrupting crystalline lead sulfate deposits in the battery 20 (for example, as discussed below regarding the surge pulse generator 160 illustrated in FIG. 10). Accordingly, the effects of sulfation may be ameliorated or avoided.

In accordance with one example, the battery monitoring device 10 includes one or more light-emitting diodes 115 (LEDs) as warning indicators for alerting an operator when the probe 130 detects that the electrolyte level 29 is outside of acceptable levels. When the level sensor 151 detects that the electrolyte level 29 is lower than a threshold level, for example, the LED 115 may light up, or flash, in order to indicate to the operator that the electrolyte 29 should be replenished. As a result, the operator can conveniently and rapidly determine whether or not the battery requires additional water or electrolyte fluid, without necessarily having to manually open and examine any vent caps or valves.

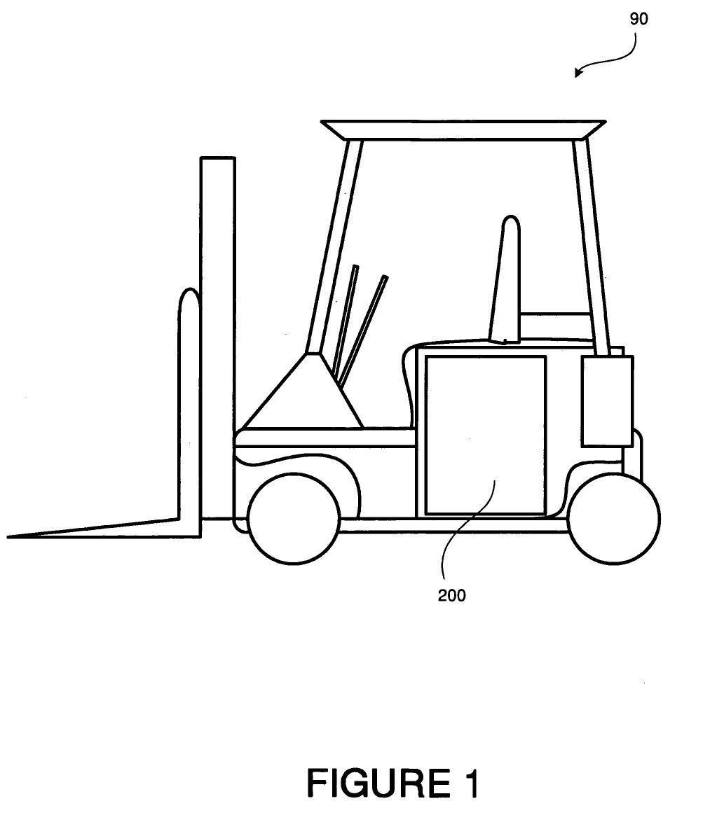

The warning indicator 115 may operate at a brightness level sufficient to alert the operator even when the battery monitoring device 10 is fully or partially obscured or enclosed. In one example embodiment, the battery monitoring device 10 may be installed to a battery 20 within the battery compartment underneath the seat of a forklift machine 90, such as illustrated in FIG. 1. When the electrolyte level 29 falls below the acceptable threshold, the LED warning indicator 115 of the battery monitoring device 10 then flashes red with an intensity sufficient such that the red light of the LED 115 diffuses outside of the battery compartment and may be visible even when the battery compartment is closed. The operator may therefore become aware of the low electrolyte level even when the warning indicator activates during operation of the forklift, for example. Alternatively, the warning indicator 115 may include a buzzer, alarm, or other audible signal, either in addition to a visual indicator such as an LED or in lieu thereof.

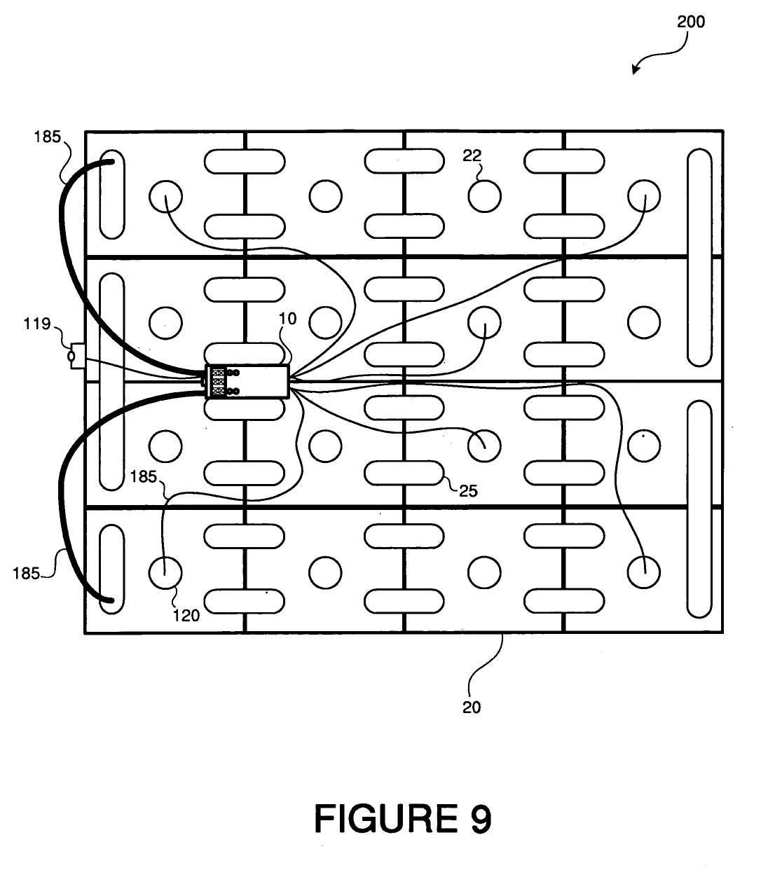

The battery monitoring device 10 may also include a display 117 or readout for indicating information regarding the battery to the operator. As illustrated in FIG. 3B, for example, the display 117 may include a seven-segment LED panel or a liquid-crystal display (LCD) that can display the electrolyte level, temperature, occurrence of sulfation, or other information detected by the probe. When appropriate, the display 117 may also present textual instructions to inform the operator of any steps that should be taken in order to resolve low electrolyte level or to prolong battery life or improve battery performance, based on the status of the battery as ascertained by the battery monitoring device. In one example arrangement, the display initially presents the temperature of the battery (for example, for a few seconds), and then cycles to display the electrolyte level, and then the internal resistance of the battery. Moreover, where the battery monitoring device 10 is connected to more than one battery 20 in a battery array 200, as shown in FIG. 9, then the display 117 may cycle through the relevant information for each such cell in a serial manner.

As illustrated in FIG. 9, a summary LED 119 may also be provided, which provides a simple “OK” or “not OK” message. For example, the summary LED 119 may be disposed in the cab of the forklift 90, connected to the battery monitoring device 10 disposed on the array of batteries 200 (which may be partially or entirely obscured from the view of the operator during normal use of the forklift 90). When all of the battery characteristics monitored by the battery monitoring device 10 are within acceptable ranges (e.g., the electrolyte level 29 is sufficiently full as detected by the electrolyte sensor 151, and the temperature is not above a pre-set threshold as detected by the temperature sensor 156), then the summary LED 119 flashes green light to indicate “OK” status. On the other hand, when any one or more of the battery characteristics are not within the acceptable range of values, then the summary LED flashes red to indicate “not OK” status. The operator may then perform further investigation by examining the LEDs 115 or seven-segment display 117 to determine the nature of the problem, and take corrective action. As a result, the operator's work process is not made more complicated than necessary, by virtue of the simple “OK”/“not OK” status information provided by the summary LED 119.

The battery monitoring device 10 may also include a data acquisition module 180 such as a wireless transmitter for communicating battery status information to a remote computer. In one example, the battery monitoring device 10 includes a wireless Ethernet transceiver that can communicate the electrolyte level, temperature, desulfation activities performed by the battery monitoring device, and/or other information regarding the battery to a computer that collects and stores the information. Also, or alternatively to the wireless transmitter, the battery monitoring device 10 may include a non-volatile data storage device such as an EEPROM, battery-backed RAM, or hard disk drive for storing monitored battery characteristics, which may be read out by a PEM device or serial cable at a later time. As a result, the operating history of the battery can be monitored and analyzed.

In an example embodiment, the battery monitoring device includes a surge pulse generator 160 having an inductive coil 165 and a field-effect transistor (FET) 166 for controlling electric current in the coil. The surge pulse generator 160 can deliver a pulse of electricity to the battery 20 in order to disrupt or remove lead sulfate deposits.

The surge pulse generator 160 may be controlled to deliver the surge pulse at a particular interval, in order to provide optimal desulfation effects to the battery. The interval may be pre-set to a particular period of time, such as a particular number of pulses provided per second, or may alternatively be adjusted by the battery monitoring device as appropriate based on information ascertained by the battery monitoring device regarding the battery.

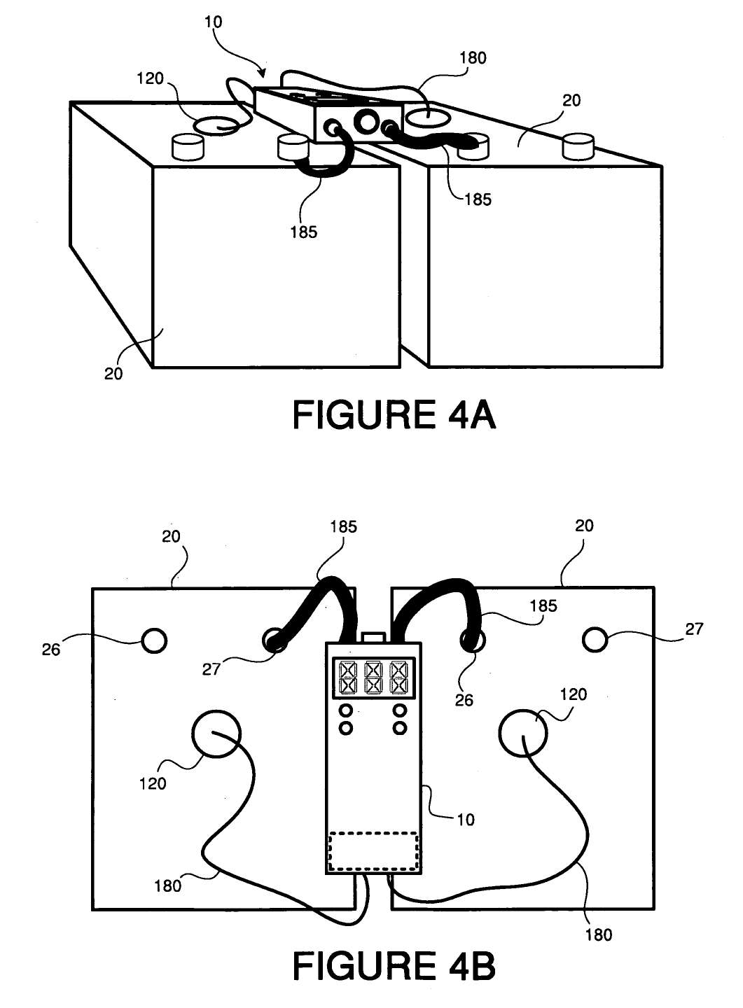

The battery monitoring device 10 may draw the power necessary for its operation from the battery 20 being monitored. As illustrated in FIGS. 4A, 4B and 9, for example, at least one example embodiment of the battery monitoring device 10 includes power lines 185 that connect to an anode 26 and a cathode 26 of a battery 20. As a result, auxiliary or external power supplies may be omitted.

FIG. 9 shows an example battery monitoring device 10 having six probes 130 connected to six different batteries 20 in a battery array 200, such as used in industrial forklifts 90. Moreover, the battery monitoring device 10 may instead include only one probe, or include more than six probes, as appropriate for the intended duty of the battery monitor 10 and the type and size of the array of batteries 200 that is being monitored.

In order to control the current delivered by the surge pulse generator 160, the battery monitoring device 10 may include buttons or other user-operable switches for switching selection of the strength of the output surge pulse among varying current levels. In one example embodiment, the battery monitoring device 10 includes two switch buttons that permit the surge pulse current level to be selected from among three strength levels.

As an example, when the battery monitoring device 10 is supplied to a customer or installed on a battery array 200, the operator or a technician may select the optimal pulse strength for the type of battery being monitored. This selection may be set and remembered by the battery monitoring device 10 so that the appropriate pulse strength is then delivered by the surge pulse generator 160.

Accordingly, in accordance with at least one example embodiment, a battery monitoring device may be provided that can monitor battery status such as electrolyte level and temperature. Also, in accordance with a further embodiment, a battery monitoring device can perform desulfation at appropriate intervals, in one integrated unit that can be installed to existing batteries without requiring tapping or drilling of the battery casing.

As noted above, sulfation can present a significant problem in batteries that are stored or remain unused for periods of time. Accordingly, the present battery monitoring device 10 according to at least one embodiment monitors the electrolyte level 29 using the electrolyte sensor 151 and also monitors the temperature of the battery 20 via the probe 130 and temperature sensor 156 to determine whether the battery 20 requires servicing. When such is the case, the battery monitoring device 10 can inform the operator. Accordingly, battery life and operating performance can be extended and enhanced.

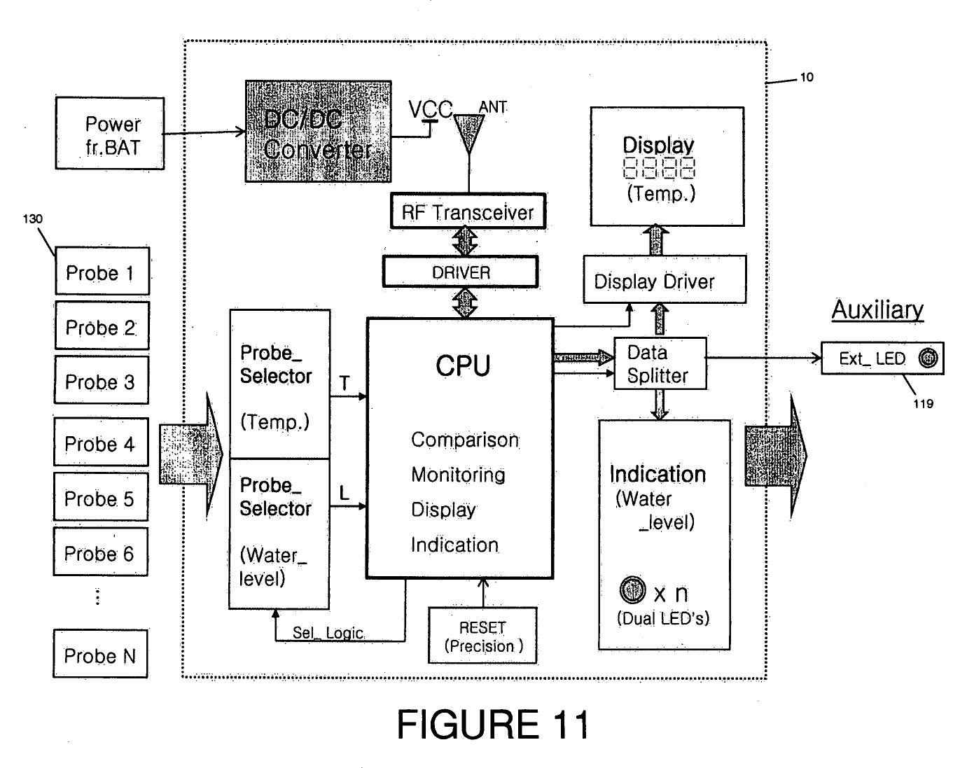

FIG. 10 is a block diagram of the functional units, and FIG. 11 is a block-level circuit diagram of a battery monitoring device 10 in accordance with an example embodiment, in which the battery monitoring device 10 includes two PCB boards (termed “upper” and “lower” for convenience of explanation), a seven-segment display 117, and a set of probes 130. One of the two PCB boards includes a central processing unit (CPU), such as a microcontroller or other microprocessor, as well as a display controller for controlling the output of the seven-segment display, and a DC converter and conditioning circuit for conditioning and delivering operating power to the components of the battery monitoring device. This PCB board is communicatively connected to the second PCB board, which includes a surge pulse generator and a noise filter. The noise filter removes potentially disruptive spikes or high-frequency electrical noise that may be received from the battery.

As shown in FIGS. 10 and 11, the CPU controls the operation of the battery monitoring device and may include a Freescale™ 68HC11™, INTEL™ Xscale™, MIPS™ R4000™ or related architecture, ARM™, or any other microprocessor, a PIC, a single-IC computer, or a microcontroller suitable for controlling the operation of the display, the surge pulse generator, and probe. The CPU may also include a working memory, such as DRAM or SRAM, and/or a non-volatile storage memory (NVRAM) such as battery-backed DRAM, a magnetic medium such as a hard disk, an EEPROM, and/or other memory suitable for maintaining data despite loss of main power. Also as illustrated in FIGS. 10 and 11, a signal conformation circuit may be provided for converting a FET generating signal from the generated pulse in the CPU.

The CPU may further be connected to a data acquisition module, such as a serial port or wireless transmitter antenna, for communicating monitored battery characteristics to a database or other computer.

Also, the battery monitoring device 10 is not limited to use with forklifts. Rather, the battery monitoring device 10 can be applied to any battery-powered equipment using lead oxide-based batteries, such as automobiles, building or street cleaning equipment, ice resurfacers, military hardware, or any other such devices.

Although various examples and illustrative embodiments have been discussed, the present invention is not limited only to these examples. Rather, various modifications, variations and alterations are understood to be within the scope of the present invention, and are readily recognizable to those skilled in the art.

1. A battery monitoring device, comprising:
a probe configured to be inserted into a pre-existing valve of a battery;
a an electrolyte sensor disposed in the probe and configured to detect an electrolyte level in the battery;
a temperature sensor disposed in the probe and configured to detect a temperature of the battery; and
a warning indicator configured to indicate when an electrolyte level of the battery is below a threshold level.

2. The battery monitoring device according to claim 1, further comprising:
a display configured to indicate the temperature detected by the temperature sensor.

3. The battery monitoring device according to claim 1, wherein the warning indicator includes a light-emitting diode.

4. The battery monitoring device according to claim 1, further comprising:
a surge pulse generator configured to apply an electrical pulse to the battery.

5. The battery monitoring device according to claim 4, further comprising:
a microprocessor configured to cause the surge pulse generator to deliver the electrical pulse at a predetermined interval.

6. The battery monitoring device according to claim 4, wherein the surge pulse generator includes:
an inductive coil; and
a field-effect transistor configured to control a current flowing through the inductive coil.

7. The battery monitoring device according to claim 4, further comprising a switch configured to adjust an output of the surge pulse generator.

8. The battery monitoring device according to claim 7, wherein the switch is further configured to adjust the output of the surge pulse generator among at least three levels.

9. The battery monitoring device according to claim 2, wherein the display includes a seven-segment display.

10. The battery monitoring device according to claim 2, further comprising a microprocessor configured to cycle the output of the display between the temperature of the battery, an electrolyte level of the battery, an internal resistance, and/or a relative degree of sulfation of the battery.

11. The battery monitoring device according to claim 1, further comprising a DC converter configured to supply operating power for the battery monitoring device from a power output of the battery.

12. The battery monitoring device according to claim 4, wherein the surge pulse generator delivers a surge pulse to the battery when the temperature of the battery remains below a threshold temperature for at least a pre-determined period of time.

13. The battery monitoring device according to claim 4, wherein the surge pulse generator delivers a surge pulse to the battery in parallel to a charging current when the battery is being charged.

14. The battery monitoring device according to claim 1, further comprising an electrolyte level sensor and a temperature sensor provided with the probe.

15. The battery monitoring device according to claim 1, further comprising a valve interface provided at an upper portion of the probe and configured to detachably retain the probe within the valve and to provide a water-tight seal with the valve.

16. The battery monitoring device according to claim 15, wherein the valve interface includes a retaining mechanism compatible with an existing vent cap provided with the battery.

17. The battery monitoring device according to claim 1, further comprising a wireless transmitter configured to communicate information regarding the battery.

18. A battery probe comprising:
a sensor sheath configured to protrude into a battery;
an electrolyte sensor disposed in the sensor sheath and configured to detect a level of electrolyte in the battery; and
a probe retainer connected to the sensor sheath and electrolyte sensor, and configured to detachably connect to a valve opening of the battery.

19. The battery probe according to claim 18, further comprising a temperature sensor disposed in the sensor sheath and configured to detect a temperature of the battery.

20. The battery probe according to claim 18, wherein an interior surface of the sensor sheath is flush against the electrolyte sensor and is configured to provide a water-tight seal.
